(19) United States
(12) Patent Application Publication
(10) Pub. No.: US 2025/0077741 A1
(43) Pub. Date: Mar. 6, 2025

(54) Systems and Methods for Autonomous Vehicle Validation

(71) Applicant: Aurora Operations, Inc., Mountain View, CA (US)

(72) Inventor: Chris Lorena Nogales Iturri, Sunnyvale, CA (US)

(21) Appl. No.: 18/458,376

(22) Filed: Aug. 30, 2023

(51) Int. Cl. G06F 30/27; B60W 50/10; B60W 60/00

(52) U.S. Cl. CPC G06F 30/27; B60W 50/10; B60W 60/00; B60W 2050/0075

(57) ABSTRACT

An example method includes (a) obtaining reference decision data describing a reference decision associated with navigating a driving scenario, wherein the reference decision data comprises a target action and a corresponding object identifier associated with the target action; and label data that comprises a validity interval associated with the reference decision, the validity interval indicating a time period of the driving scenario during which the reference decision is valid; (b) simulating a performance of a system under test (SUT) in the driving scenario to generate SUT decision data describing one or more SUT decisions associated with controlling an autonomous vehicle to navigate the driving scenario; and (c) determining, based on a comparison of the reference decision data and the SUT decision data, a validation state for the SUT.

### BACKGROUND

An autonomous platform can process data to perceive an environment through which the autonomous platform travels. For example, an autonomous vehicle can perceive its environment using a variety of sensors and identify objects around the autonomous vehicle. The autonomous vehicle can identify an appropriate path through the perceived surrounding environment and navigate along the path with minimal or no human input.

### SUMMARY

Example implementations of the present disclosure relate to systems and techniques for training and validating autonomous vehicle control systems. An autonomous vehicle control system can include components that are developed and refined over time. To evaluate the performance of a particular component or system under test (SUT), a computing system can validate the SUT by comparing decisions made by the SUT with decisions of human exemplars. A computing system can validate the SUT based on a comparison of the SUT output and a set of reference data. A computing system can obtain reference data from human users. For instance, the test scenario can be a driving scenario. The SUT can output decisions for navigating the driving scenario (e.g., “stop at crosswalk,” “slow down when passing parked cars,” etc.). Human users can input decisions that they would make in the same scenario. A computing system can compare decisions made by the SUT and the decisions input by the human users. In this manner, for instance, a computing system can validate the performance of a component by determining how similarly the component mimics human behavior.

A simulation system can simulate the SUT to obtain its decisions for a given driving scenario. The simulation system can simulate the SUT in driving scenarios sampled from real-world scenarios (e.g., sampled from log data recorded over real-world driving miles). In this manner, for instance, the simulation system can inject the SUT into real-world driving scenarios for comparing the SUT decision-making with human decisions for the same driving scenarios. The simulation system can simulate the SUT in synthetic driving scenarios. For instance, the simulation system can generate driving scenarios that are configured to realistically synthesize an environment for testing the SUT. The simulation system can log the synthetic scenarios encountered by the SUT for presentation to a human user who can view the synthetic scenarios. The human user can input a decision for how to navigate the synthetic driving scenario. In this manner, for instance, a computing system can compare the SUT decision-making with human decisions for the same driving scenarios.

Validation techniques according to the present disclosure can advantageously facilitate holistic evaluation of the effect of individual model updates on overall outcomes achieved by the autonomous vehicle. Using high-level decisions as ground truth (e.g., in addition to or in lieu of more granular labeled data) can capture higher-order effects of model performance that may not be apparent when evaluating on granular prediction or classification tasks. For instance, an SUT can implement a number of complex models to perceive and understand an environment and generate and execute plans for traversing the environment. By evaluating performance holistically against a high-level decision, a computing system can evaluate changes to individual operational models based on the effects on overall performance of the vehicle as a predictable and human-like road user. In this manner, developers can prioritize performance differences that cause deviations from overall expected behavior as compared to performance differences that do not ultimately contribute to overall behavioral deficiencies. Accordingly, validation techniques according to the present disclosure can assist in more efficient and effective model development.

Validation techniques according to the present disclosure can thus evaluate the performance of an SUT without necessarily requiring hand-tuned, hard-coded complex costs and arbitrary thresholds and envelopes. For instance, validation techniques according to the present disclosure can leverage the expertise of human drivers. For instance, a human driver might cover the brakes or decrease acceleration when driving past a merging zone of a roadway when there are other vehicles merging into the driver's lane, even though the driver generally has the right of way in the lane. The human driver's choice encodes a complex balancing of risk and cost: the risk of a surprise early cut-in by another vehicle, the cost of being unprepared for the surprise early cut-in, and the cost to the driver of slowing down. Accordingly, at scale, the collective behavior of human exemplars can provide a framework for understanding what behavior is expected of vehicles in different driving scenarios. Accordingly, one example technique for evaluating autonomous vehicle behavior (and the operational systems that control the behavior) includes comparison to human exemplars.

Validation techniques according to the present disclosure can also advantageously obtain direct comparisons with human decisions without requiring extensive accumulation of actual or simulated driving miles that align with the recorded behavior of human experts. Such accumulation can consume considerable resources (e.g., computational resources, energy resources, etc.) and be time consuming, even if simulated. Advantageously, a computing system can simulate driving scenarios in which the SUT is placed. A human user can view and respond to information descriptive of that simulated driving scenario, thereby facilitating direct comparisons with human decision-making at any sample size desired.

Validation techniques according to the present disclosure can also advantageously facilitate holistic evaluation of the effect of individual model development on overall outcomes achieved by the autonomous vehicle. For instance, autonomy computing pipelines can implement a number of complex systems and models to perceive and understand an environment and generate and execute plans for traversing the environment. By evaluating performance holistically against an exemplar baseline, changes to individual operational systems and systems can be evaluated based on the effects on overall performance of the vehicle. In this manner, performance differences that cause deviations from exemplar behavior can be prioritized for development over performance differences that do not ultimately contribute to performance defects. Accordingly, validation techniques according to the present disclosure can assist in more efficient and effective system and model development.

For example, in an aspect, the present disclosure provides an example method for validating an operational system for operating an autonomous vehicle. The example method can include obtaining reference decision data describing a reference decision associated with navigating a driving scenario. The example method can include simulating a performance of a system under test (SUT) in the driving scenario to generate SUT decision data describing one or more SUT decisions associated with controlling an autonomous vehicle to navigate the driving scenario. The example method can include determining, based on a comparison of the reference decision data and the SUT decision data, a validation state for the component.

For example, in an aspect, the present disclosure provides an example computing system. In some implementations, the example computing system includes one or more processors and one or more non-transitory computer-readable media storing instructions that are executable by the one or more processors to cause the computing system to perform operations. The operations can include obtaining reference decision data describing a reference decision associated with navigating a driving scenario. The operations can include simulating a performance of a system under test (SUT) in the driving scenario to generate SUT decision data describing one or more SUT decisions associated with controlling an autonomous vehicle to navigate the driving scenario. The operations can include determining, based on a comparison of the reference decision data and the SUT decision data, a validation state for the component.

For example, in an aspect, the present disclosure provides for one or more example non-transitory computer-readable media storing instructions that are executable to cause one or more processors to perform operations. The operations can include obtaining reference decision data describing a reference decision associated with navigating a driving scenario. The operations can include simulating a performance of a system under test (SUT) in the driving scenario to generate SUT decision data describing one or more SUT decisions associated with controlling an autonomous vehicle to navigate the driving scenario. The operations can include determining, based on a comparison of the reference decision data and the SUT decision data, a validation state for the component.

Other example aspects of the present disclosure are directed to other systems, methods, vehicles, apparatuses, tangible non-transitory computer-readable media, and devices for performing functions described herein. These and other features, aspects and advantages of various implementations will become better understood with reference to the following description and appended claims. The accompanying drawings, which are incorporated in and constitute a part of this specification, illustrate implementations of the present disclosure and, together with the description, serve to explain the related principles.

### BRIEF DESCRIPTION OF THE DRAWINGS

Detailed discussion of implementations directed to one of ordinary skill in the art are set forth in the specification, which makes reference to the appended figures, in which:

FIG. 1 is a block diagram of an example operational scenario, according to some implementations of the present disclosure;

FIG. 2 is a block diagram of an example system, according to some implementations of the present disclosure;

FIG. 3A is a representation of an example operational environment, according to some implementations of the present disclosure;

FIG. 3B is a representation of an example map of an operational environment, according to some implementations of the present disclosure;

FIG. 3C is a representation of an example operational environment, according to some implementations of the present disclosure;

FIG. 3D is a representation of an example map of an operational environment, according to some implementations of the present disclosure;

FIG. 4 is a block diagram of an example system for performing system validation, according to some implementations of the present disclosure;

FIG. 5A is an illustration of a driving scenario for performing system validation, according to some implementations of the present disclosure;

FIG. 5B is another illustration of a driving scenario for performing system validation, according to some implementations of the present disclosure;

FIG. 6 is an illustration of an example user interface for performing system validation, according to some implementations of the present disclosure;

FIG. 7 is a block diagram of a simulation dataflow for performing system validation, according to some implementations of the present disclosure;

FIG. 8 is a block diagram of a simulation dataflow for performing system validation, according to some implementations of the present disclosure;

FIG. 9 is a flowchart of an example method for system validation, according to some implementations of the present disclosure;

FIG. 10 is a flowchart of an example method for system validation, according to some implementations of the present disclosure;

FIG. 11 is a flowchart of an example method for training and validating a machine-learned operational system, according to some implementations of the present disclosure; and

FIG. 12 is a block diagram of an example computing system for performing system validation, according to some implementations of the present disclosure.

### DETAILED DESCRIPTION

The following describes the technology of this disclosure within the context of an autonomous vehicle for example purposes only. As described herein, the technology described herein is not limited to an autonomous vehicle and can be implemented for or within other autonomous platforms and other computing systems.

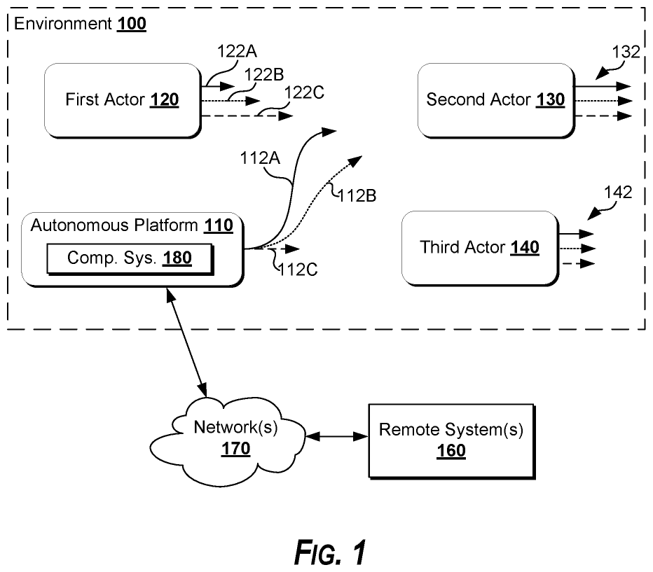

With reference to FIGS. 1-12, example implementations of the present disclosure are discussed in further detail. FIG. 1 is a block diagram of an example operational scenario, according to some implementations of the present disclosure. In the example operational scenario, an environment 100 contains an autonomous platform 110 and a number of objects, including first actor 120, second actor 130, and third actor 140. In the example operational scenario, the autonomous platform 110 can move through the environment 100 and interact with the object(s) that are located within the environment 100 (e.g., first actor 120, second actor 130, third actor 140, etc.). The autonomous platform 110 can optionally be configured to communicate with remote system(s) 160 through network(s) 170.

The environment 100 may be or include an indoor environment (e.g., within one or more facilities, etc.) or an outdoor environment. An indoor environment, for example, may be an environment enclosed by a structure such as a building (e.g., a service depot, maintenance location, manufacturing facility, etc.). An outdoor environment, for example, may be one or more areas in the outside world such as, for example, one or more rural areas (e.g., with one or more rural travel ways, etc.), one or more urban areas (e.g., with one or more city travel ways, highways, etc.), one or more suburban areas (e.g., with one or more suburban travel ways, etc.), or other outdoor environments.

The autonomous platform 110 may be any type of platform configured to operate within the environment 100. For example, the autonomous platform 110 may be a vehicle configured to autonomously perceive and operate within the environment 100. The vehicles may be a ground-based autonomous vehicle such as, for example, an autonomous car, truck, van, etc. The autonomous platform 110 may be an autonomous vehicle that can control, be connected to, or be otherwise associated with implements, attachments, and/or accessories for transporting people or cargo. This can include, for example, an autonomous tractor optionally coupled to a cargo trailer. Additionally, or alternatively, the autonomous platform 110 may be any other type of vehicle such as one or more aerial vehicles, water-based vehicles, space-based vehicles, other ground-based vehicles, etc.

The autonomous platform 110 may be configured to communicate with the remote system(s) 160. For instance, the remote system(s) 160 can communicate with the autonomous platform 110 for assistance (e.g., navigation assistance, situation response assistance, etc.), control (e.g., fleet management, remote operation, etc.), maintenance (e.g., updates, monitoring, etc.), or other local or remote tasks. In some implementations, the remote system(s) 160 can provide data indicating tasks that the autonomous platform 110 should perform. For example, as further described herein, the remote system(s) 160 can provide data indicating that the autonomous platform 110 is to perform a trip/service such as a user transportation trip/service, delivery trip/service (e.g., for cargo, freight, items), etc.

The autonomous platform 110 can communicate with the remote system(s) 160 using the network(s) 170. The network(s) 170 can facilitate the transmission of signals (e.g., electronic signals, etc.) or data (e.g., data from a computing device, etc.) and can include any combination of various wired (e.g., twisted pair cable, etc.) or wireless communication mechanisms (e.g., cellular, wireless, satellite, microwave, radio frequency, etc.) or any desired network topology (or topologies). For example, the network(s) 170 can include a local area network (e.g., intranet, etc.), a wide area network (e.g., the Internet, etc.), a wireless LAN network (e.g., through Wi-Fi, etc.), a cellular network, a SATCOM network, a VHF network, a HF network, a WiMAX based network, or any other suitable communications network (or combination thereof) for transmitting data to or from the autonomous platform 110.

As shown for example in FIG. 1, environment 100 can include one or more objects. The object(s) may be objects not in motion or not predicted to move (“static objects”) or object(s) in motion or predicted to be in motion (“dynamic objects” or “actors”). In some implementations, the environment 100 can include any number of actor(s) such as, for example, one or more pedestrians, animals, vehicles, etc. The actor(s) can move within the environment according to one or more actor trajectories. For instance, the first actor 120 can move along any one of the first actor trajectories 122A-C, the second actor 130 can move along any one of the second actor trajectories 132, the third actor 140 can move along any one of the third actor trajectories 142, etc.

As further described herein, the autonomous platform 110 can utilize its autonomy system(s) to detect these actors (and their movement) and plan its motion to navigate through the environment 100 according to one or more platform trajectories 112A-C. The autonomous platform 110 can include onboard computing system(s) 180. The onboard computing system(s) 180 can include one or more processors and one or more memory devices. The one or more memory devices can store instructions executable by the one or more processors to cause the one or more processors to perform operations or functions associated with the autonomous platform 110, including implementing its autonomy system(s).

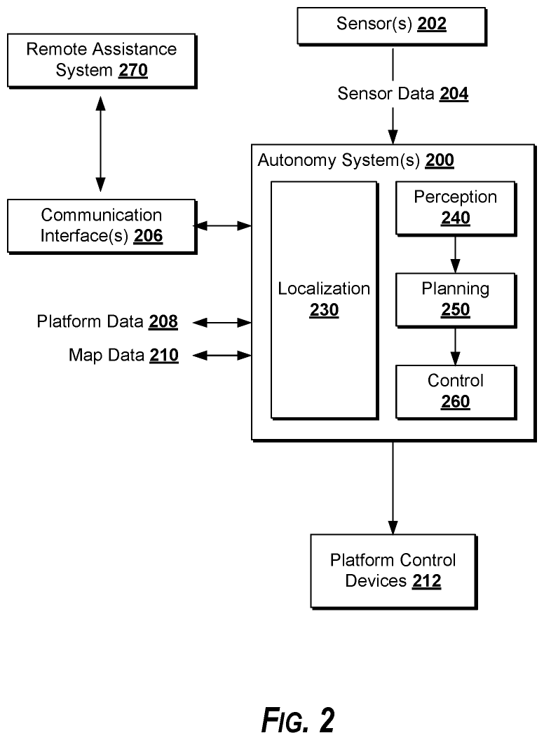

FIG. 2 is a block diagram of an example autonomy system 200 for an autonomous platform, according to some implementations of the present disclosure. In some implementations, the autonomy system 200 can be implemented by a computing system of the autonomous platform (e.g., the onboard computing system(s) 180 of the autonomous platform 110). The autonomy system 200 can operate to obtain inputs from sensor(s) 202 or other input devices. In some implementations, the autonomy system 200 can additionally obtain platform data 208 (e.g., map data 210) from local or remote storage. The autonomy system 200 can generate control outputs for controlling the autonomous platform (e.g., through platform control devices 212, etc.) based on sensor data 204, map data 210, or other data. The autonomy system 200 may include different subsystems for performing various autonomy operations. The subsystems may include a localization system 230, a perception system 240, a planning system 250, and a control system 260. The localization system 230 can determine the location of the autonomous platform within its environment; the perception system 240 can detect, classify, and track objects and actors in the environment; the planning system 250 can determine a trajectory for the autonomous platform; and the control system 260 can translate the trajectory into vehicle controls for controlling the autonomous platform. The autonomy system 200 can be implemented by one or more onboard computing system(s). The subsystems can include one or more processors and one or more memory devices. The one or more memory devices can store instructions executable by the one or more processors to cause the one or more processors to perform operations or functions associated with the subsystems. The computing resources of the autonomy system 200 can be shared among its subsystems, or a subsystem can have a set of dedicated computing resources.

In some implementations, the autonomy system 200 can be implemented for or by an autonomous vehicle (e.g., a ground-based autonomous vehicle). The autonomy system 200 can perform various processing techniques on inputs (e.g., the sensor data 204, the map data 210) to perceive and understand the vehicle's surrounding environment and generate an appropriate set of control outputs to implement a vehicle motion plan (e.g., including one or more trajectories) for traversing the vehicle's surrounding environment (e.g., environment 100 of FIG. 1, etc.). In some implementations, an autonomous vehicle implementing the autonomy system 200 can drive, navigate, operate, etc. with minimal or no interaction from a human operator (e.g., driver, pilot, etc.).

In some implementations, the autonomous platform can be configured to operate in a plurality of operating modes. For instance, the autonomous platform can be configured to operate in a fully autonomous (e.g., self-driving, etc.) operating mode in which the autonomous platform is controllable without user input (e.g., can drive and navigate with no input from a human operator present in the autonomous vehicle or remote from the autonomous vehicle, etc.). The autonomous platform can operate in a semi-autonomous operating mode in which the autonomous platform can operate with some input from a human operator present in the autonomous platform (or a human operator that is remote from the autonomous platform). In some implementations, the autonomous platform can enter into a manual operating mode in which the autonomous platform is fully controllable by a human operator (e.g., human driver, etc.) and can be prohibited or disabled (e.g., temporary, permanently, etc.) from performing autonomous navigation (e.g., autonomous driving, etc.). The autonomous platform can be configured to operate in other modes such as, for example, park or sleep modes (e.g., for use between tasks such as waiting to provide a trip/service, recharging, etc.). In some implementations, the autonomous platform can implement vehicle operating assistance technology (e.g., collision mitigation system, power assist steering, etc.), for example, to help assist the human operator of the autonomous platform (e.g., while in a manual mode, etc.).

Autonomy system 200 can be located onboard (e.g., on or within) an autonomous platform and can be configured to operate the autonomous platform in various environments. The environment may be a real-world environment or a simulated environment. In some implementations, one or more simulation computing devices can simulate one or more of: the sensors 202, the sensor data 204, communication interface(s) 206, the platform data 208, or the platform control devices 212 for simulating operation of the autonomy system 200.

In some implementations, the autonomy system 200 can communicate with one or more networks or other systems with the communication interface(s) 206. The communication interface(s) 206 can include any suitable components for interfacing with one or more network(s) (e.g., the network(s) 170 of FIG. 1, etc.), including, for example, transmitters, receivers, ports, controllers, antennas, or other suitable components that can help facilitate communication. In some implementations, the communication interface(s) 206 can include a plurality of components (e.g., antennas, transmitters, or receivers, etc.) that allow it to implement and utilize various communication techniques (e.g., multiple-input, multiple-output (MIMO) technology, etc.).

In some implementations, the autonomy system 200 can use the communication interface(s) 206 to communicate with one or more computing devices that are remote from the autonomous platform (e.g., the remote system(s) 160) over one or more network(s) (e.g., the network(s) 170). For instance, in some examples, one or more inputs, data, or functionalities of the autonomy system 200 can be supplemented or substituted by a remote system communicating over the communication interface(s) 206. For instance, in some implementations, the map data 210 can be downloaded over a network to a remote system using the communication interface(s) 206. In some examples, one or more of the localization system 230, the perception system 240, the planning system 250, or the control system 260 can be updated, influenced, nudged, communicated with, etc. by a remote system for assistance, maintenance, situational response override, management, etc.

The sensor(s) 202 can be located onboard the autonomous platform. In some implementations, the sensor(s) 202 can include one or more types of sensor(s). For instance, one or more sensors can include image capturing device(s) (e.g., visible spectrum cameras, infrared cameras, etc.). Additionally, or alternatively, the sensor(s) 202 can include one or more depth capturing device(s). For example, the sensor(s) 202 can include one or more Light Detection and Ranging (LIDAR) sensor(s) or Radio Detection and Ranging (RADAR) sensor(s). The sensor(s) 202 can be configured to generate point data descriptive of at least a portion of a three-hundred-and-sixty-degree view of the surrounding environment. The point data can be point cloud data (e.g., three-dimensional LIDAR point cloud data, RADAR point cloud data). In some implementations, one or more of the sensor(s) 202 for capturing depth information can be fixed to a rotational device in order to rotate the sensor(s) 202 about an axis. The sensor(s) 202 can be rotated about the axis while capturing data in interval sector packets descriptive of different portions of a three-hundred-and-sixty-degree view of a surrounding environment of the autonomous platform. In some implementations, one or more of the sensor(s) 202 for capturing depth information can be solid state.

The sensor(s) 202 can be configured to capture the sensor data 204 indicating or otherwise being associated with at least a portion of the environment of the autonomous platform. The sensor data 204 can include image data (e.g., 2D camera data, video data, etc.), RADAR data, LIDAR data (e.g., 3D point cloud data, etc.), audio data, or other types of data. In some implementations, the autonomy system 200 can obtain input from additional types of sensors, such as inertial measurement units (IMUs), altimeters, inclinometers, odometry devices, location or positioning devices (e.g., GPS, compass), wheel encoders, or other types of sensors. In some implementations, the autonomy system 200 can obtain sensor data 204 associated with particular component(s) or system(s) of an autonomous platform. This sensor data 204 can indicate, for example, wheel speed, component temperatures, steering angle, cargo or passenger status, etc. In some implementations, the autonomy system 200 can obtain sensor data 204 associated with ambient conditions, such as environmental or weather conditions. In some implementations, the sensor data 204 can include multi-modal sensor data. The multi-modal sensor data can be obtained by at least two different types of sensor(s) (e.g., of the sensors 202) and can indicate static object(s) or actor(s) within an environment of the autonomous platform. The multi-modal sensor data can include at least two types of sensor data (e.g., camera and LIDAR data). In some implementations, the autonomous platform can utilize the sensor data 204 for sensors that are remote from (e.g., offboard) the autonomous platform. This can include for example, sensor data 204 captured by a different autonomous platform.

The autonomy system 200 can obtain the map data 210 associated with an environment in which the autonomous platform was, is, or will be located. The map data 210 can provide information about an environment or a geographic area. For example, the map data 210 can provide information regarding the identity and location of different travel ways (e.g., roadways, etc.), travel way segments (e.g., road segments, etc.), buildings, or other items or objects (e.g., lampposts, crosswalks, curbs, etc.); the location and directions of boundaries or boundary markings (e.g., the location and direction of traffic lanes, parking lanes, turning lanes, bicycle lanes, other lanes, etc.); traffic control data (e.g., the location and instructions of signage, traffic lights, other traffic control devices, etc.); obstruction information (e.g., temporary or permanent blockages, etc.); event data (e.g., road closures/traffic rule alterations due to parades, concerts, sporting events, etc.); nominal vehicle path data (e.g., indicating an ideal vehicle path such as along the center of a certain lane, etc.); or any other map data that provides information that assists an autonomous platform in understanding its surrounding environment and its relationship thereto. In some implementations, the map data 210 can include high-definition map information. Additionally, or alternatively, the map data 210 can include sparse map data (e.g., lane graphs, etc.). In some implementations, the sensor data 204 can be fused with or used to update the map data 210 in real-time.

The autonomy system 200 can include the localization system 230, which can provide an autonomous platform with an understanding of its location and orientation in an environment. In some examples, the localization system 230 can support one or more other subsystems of the autonomy system 200, such as by providing a unified local reference frame for performing. e.g., perception operations, planning operations, or control operations.

In some implementations, the localization system 230 can determine a current position of the autonomous platform. A current position can include a global position (e.g., respecting a georeferenced anchor, etc.) or relative position (e.g., respecting objects in the environment, etc.). The localization system 230 can generally include or interface with any device or circuitry for analyzing a position or change in position of an autonomous platform (e.g., autonomous ground-based vehicle, etc.). For example, the localization system 230 can determine position by using one or more of: inertial sensors (e.g., inertial measurement unit(s), etc.), a satellite positioning system, radio receivers, networking devices (e.g., based on IP address, etc.), triangulation or proximity to network access points or other network components (e.g., cellular towers, Wi-Fi access points, etc.), or other suitable techniques. The position of the autonomous platform can be used by various subsystems of the autonomy system 200 or provided to a remote computing system (e.g., using the communication interface(s) 206).

In some implementations, the localization system 230 can register relative positions of elements of a surrounding environment of an autonomous platform with recorded positions in the map data 210. For instance, the localization system 230 can process the sensor data 204 (e.g., LIDAR data, RADAR data, camera data, etc.) for aligning or otherwise registering to a map of the surrounding environment (e.g., from the map data 210) to understand the autonomous platform's position within that environment. Accordingly, in some implementations, the autonomous platform can identify its position within the surrounding environment (e.g., across six axes, etc.) based on a search over the map data 210. In some implementations, given an initial location, the localization system 230 can update the autonomous platform's location with incremental re-alignment based on recorded or estimated deviations from the initial location. In some implementations, a position can be registered directly within the map data 210.

In some implementations, the map data 210 can include a large volume of data subdivided into geographic tiles, such that a desired region of a map stored in the map data 210 can be reconstructed from one or more tiles. For instance, a plurality of tiles selected from the map data 210 can be stitched together by the autonomy system 200 based on a position obtained by the localization system 230 (e.g., a number of tiles selected in the vicinity of the position).

In some implementations, the localization system 230 can determine positions (e.g., relative or absolute) of one or more attachments or accessories for an autonomous platform. For instance, an autonomous platform can be associated with a cargo platform, and the localization system 230 can provide positions of one or more points on the cargo platform. For example, a cargo platform can include a trailer or other device towed or otherwise attached to or manipulated by an autonomous platform, and the localization system 230 can provide for data describing the position (e.g., absolute, relative, etc.) of the autonomous platform as well as the cargo platform. Such information can be obtained by the other autonomy systems to help operate the autonomous platform.

The autonomy system 200 can include the perception system 240, which can allow an autonomous platform to detect, classify, and track objects and actors in its environment. Environmental features or objects perceived within an environment can be those within the field of view of the sensor(s) 202 or predicted to be occluded from the sensor(s) 202. This can include object(s) not in motion or not predicted to move (static objects) or object(s) in motion or predicted to be in motion (dynamic objects/actors).

The perception system 240 can determine one or more states (e.g., current or past state(s), etc.) of one or more objects that are within a surrounding environment of an autonomous platform. For example, state(s) can describe (e.g., for a given time, time period, etc.) an estimate of an object's current or past location (also referred to as position); current or past speed/velocity; current or past acceleration; current or past heading; current or past orientation; size/footprint (e.g., as represented by a bounding shape, object highlighting, etc.); classification (e.g., pedestrian class vs. vehicle class vs. bicycle class, etc.); the uncertainties associated therewith; or other state information. In some implementations, the perception system 240 can determine the state(s) using one or more algorithms or machine-learned models configured to identify/classify objects based on inputs from the sensor(s) 202. The perception system can use different modalities of the sensor data 204 to generate a representation of the environment to be processed by the one or more algorithms or machine-learned models. In some implementations, state(s) for one or more identified or unidentified objects can be maintained and updated over time as the autonomous platform continues to perceive or interact with the objects (e.g., maneuver with or around, yield to, etc.). In this manner, the perception system 240 can provide an understanding about a current state of an environment (e.g., including the objects therein, etc.) informed by a record of prior states of the environment (e.g., including movement histories for the objects therein). Such information can be helpful as the autonomous platform plans its motion through the environment.

The autonomy system 200 can include the planning system 250, which can be configured to determine how the autonomous platform is to interact with and move within its environment. The planning system 250 can determine one or more motion plans for an autonomous platform. A motion plan can include one or more trajectories (e.g., motion trajectories) that indicate a path for an autonomous platform to follow. A trajectory can be of a certain length or time range. The length or time range can be defined by the computational planning horizon of the planning system 250. A motion trajectory can be defined by one or more waypoints (with associated coordinates). The waypoint(s) can be future location(s) for the autonomous platform. The motion plans can be continuously generated, updated, and considered by the planning system 250.

The motion planning system 250 can determine a strategy for the autonomous platform. A strategy may be a set of discrete decisions (e.g., yield to actor, reverse yield to actor, merge, lane change) that the autonomous platform makes. The strategy may be selected from a plurality of potential strategies. The selected strategy may be a lowest cost strategy as determined by one or more cost functions. The cost functions may, for example, evaluate the probability of a collision with another actor or object.

The planning system 250 can determine a desired trajectory for executing a strategy. For instance, the planning system 250 can obtain one or more trajectories for executing one or more strategies. The planning system 250 can evaluate trajectories or strategies (e.g., with scores, costs, rewards, constraints, etc.) and rank them. For instance, the planning system 250 can use forecasting output(s) that indicate interactions (e.g., proximity, intersections, etc.) between trajectories for the autonomous platform and one or more objects to inform the evaluation of candidate trajectories or strategies for the autonomous platform. In some implementations, the planning system 250 can utilize static cost(s) to evaluate trajectories for the autonomous platform (e.g., “avoid lane boundaries,” “minimize jerk,” etc.). Additionally, or alternatively, the planning system 250 can utilize dynamic cost(s) to evaluate the trajectories or strategies for the autonomous platform based on forecasted outcomes for the current operational scenario (e.g., forecasted trajectories or strategies leading to interactions between actors, forecasted trajectories or strategies leading to interactions between actors and the autonomous platform, etc.). The planning system 250 can rank trajectories based on one or more static costs, one or more dynamic costs, or a combination thereof. The planning system 250 can select a motion plan (and a corresponding trajectory) based on a ranking of a plurality of candidate trajectories. In some implementations, the planning system 250 can select a highest ranked candidate, or a highest ranked feasible candidate.

The planning system 250 can then validate the selected trajectory against one or more constraints before the trajectory is executed by the autonomous platform.

To help with its motion planning decisions, the planning system 250 can be configured to perform a forecasting function. The planning system 250 can forecast future state(s) of the environment. This can include forecasting the future state(s) of other actors in the environment. In some implementations, the planning system 250 can forecast future state(s) based on current or past state(s) (e.g., as developed or maintained by the perception system 240). In some implementations, future state(s) can be or include forecasted trajectories (e.g., positions over time) of the objects in the environment, such as other actors. In some implementations, one or more of the future state(s) can include one or more probabilities associated therewith (e.g., marginal probabilities, conditional probabilities). For example, the one or more probabilities can include one or more probabilities conditioned on the strategy or trajectory options available to the autonomous platform. Additionally, or alternatively, the probabilities can include probabilities conditioned on trajectory options available to one or more other actors.

In some implementations, the planning system 250 can perform interactive forecasting. The planning system 250 can determine a motion plan for an autonomous platform with an understanding of how forecasted future states of the environment can be affected by execution of one or more candidate motion plans. By way of example, with reference again to FIG. 1, the autonomous platform 110 can determine candidate motion plans corresponding to a set of platform trajectories 112A-C that respectively correspond to the first actor trajectories 122A-C for the first actor 120, trajectories 132 for the second actor 130, and trajectories 142 for the third actor 140 (e.g., with respective trajectory correspondence indicated with matching line styles). For instance, the autonomous platform 110 (e.g., using its autonomy system 200) can forecast that a platform trajectory 112A to more quickly move the autonomous platform 110 into the area in front of the first actor 120 is likely associated with the first actor 120 decreasing forward speed and yielding more quickly to the autonomous platform 110 in accordance with first actor trajectory 122A. Additionally or alternatively, the autonomous platform 110 can forecast that a platform trajectory 112B to gently move the autonomous platform 110 into the area in front of the first actor 120 is likely associated with the first actor 120 slightly decreasing speed and yielding slowly to the autonomous platform 110 in accordance with first actor trajectory 122B. Additionally or alternatively, the autonomous platform 110 can forecast that a platform trajectory 112C to remain in a parallel alignment with the first actor 120 is likely associated with the first actor 120 not yielding any distance to the autonomous platform 110 in accordance with first actor trajectory 122C. Based on comparison of the forecasted scenarios to a set of desired outcomes (e.g., by scoring scenarios based on a cost or reward), the planning system 250 can select a motion plan (and its associated trajectory) in view of the autonomous platform's interaction with the environment 100. In this manner, for example, the autonomous platform 110 can interleave its forecasting and motion planning functionality.

To implement selected motion plan(s), the autonomy system 200 can include a control system 260 (e.g., a vehicle control system). Generally, the control system 260 can provide an interface between the autonomy system 200 and the platform control devices 212 for implementing the strategies and motion plan(s) generated by the planning system 250. For instance, control system 260 can implement the selected motion plan/trajectory to control the autonomous platform's motion through its environment by following the selected trajectory (e.g., the waypoints included therein). The control system 260 can, for example, translate a motion plan into instructions for the appropriate platform control devices 212 (e.g., acceleration control, brake control, steering control, etc.). By way of example, the control system 260 can translate a selected motion plan into instructions to adjust a steering component (e.g., a steering angle) by a certain number of degrees, apply a certain magnitude of braking force, increase/decrease speed, etc. In some implementations, the control system 260 can communicate with the platform control devices 212 through communication channels including, for example, one or more data buses (e.g., controller area network (CAN), etc.), onboard diagnostics connectors (e.g., OBD-II, etc.), or a combination of wired or wireless communication links. The platform control devices 212 can send or obtain data, messages, signals, etc. to or from the autonomy system 200 (or vice versa) through the communication channel(s).

The autonomy system 200 can receive, through communication interface(s) 206, assistive signal(s) from remote assistance system 270. Remote assistance system 270 can communicate with the autonomy system 200 over a network (e.g., as a remote system 160 over network 170). In some implementations, the autonomy system 200 can initiate a communication session with the remote assistance system 270. For example, the autonomy system 200 can initiate a session based on or in response to a trigger. In some implementations, the trigger may be an alert, an error signal, a map feature, a request, a location, a traffic condition, a road condition, etc.

After initiating the session, the autonomy system 200 can provide context data to the remote assistance system 270. The context data may include sensor data 204 and state data of the autonomous platform. For example, the context data may include a live camera feed from a camera of the autonomous platform and the autonomous platform's current speed. An operator (e.g., human operator) of the remote assistance system 270 can use the context data to select assistive signals. The assistive signal(s) can provide values or adjustments for various operational parameters or characteristics for the autonomy system 200. For instance, the assistive signal(s) can include way points (e.g., a path around an obstacle, lane change, etc.), velocity or acceleration profiles (e.g., speed limits, etc.), relative motion instructions (e.g., convoy formation, etc.), operational characteristics (e.g., use of auxiliary systems, reduced energy processing modes, etc.), or other signals to assist the autonomy system 200.

Autonomy system 200 can use the assistive signal(s) for input into one or more autonomy subsystems for performing autonomy functions. For instance, the planning subsystem 250 can receive the assistive signal(s) as an input for generating a motion plan. For example, assistive signal(s) can include constraints for generating a motion plan. Additionally, or alternatively, assistive signal(s) can include cost or reward adjustments for influencing motion planning by the planning subsystem 250. Additionally, or alternatively, assistive signal(s) can be considered by the autonomy system 200 as suggestive inputs for consideration in addition to other received data (e.g., sensor inputs, etc.).

The autonomy system 200 may be platform agnostic, and the control system 260 can provide control instructions to platform control devices 212 for a variety of different platforms for autonomous movement (e.g., a plurality of different autonomous platforms fitted with autonomous control systems). This can include a variety of different types of autonomous vehicles (e.g., sedans, vans, SUVs, trucks, electric vehicles, combustion power vehicles, etc.) from a variety of different manufacturers/developers that operate in various different environments and, in some implementations, perform one or more vehicle services.

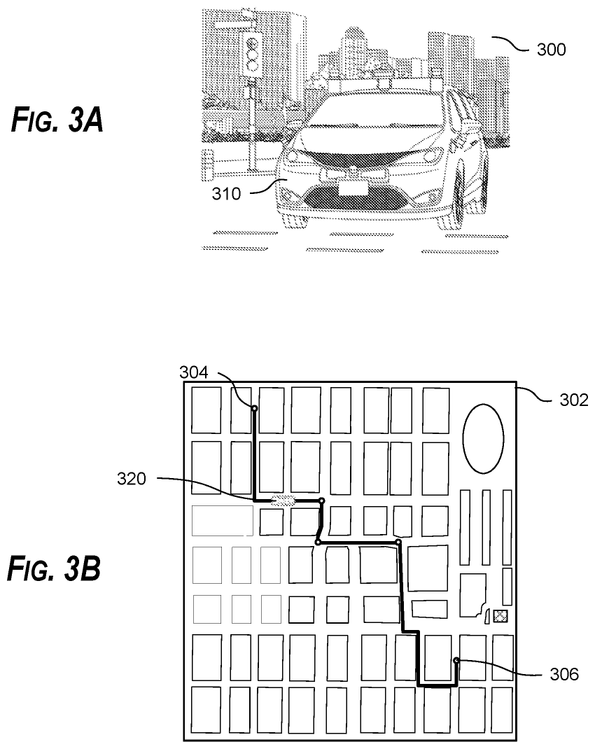

For example, with reference to FIG. 3A, an operational environment can include a dense environment 300. An autonomous platform can include an autonomous vehicle 310 controlled by the autonomy system 200. In some implementations, the autonomous vehicle 310 can be configured for maneuverability in a dense environment, such as with a configured wheelbase or other specifications. In some implementations, the autonomous vehicle 310 can be configured for transporting cargo or passengers. In some implementations, the autonomous vehicle 310 can be configured to transport numerous passengers (e.g., a passenger van, a shuttle, a bus, etc.). In some implementations, the autonomous vehicle 310 can be configured to transport cargo, such as large quantities of cargo (e.g., a truck, a box van, a step van, etc.) or smaller cargo (e.g., food, personal packages, etc.).

With reference to FIG. 3B, a selected overhead view 302 of the dense environment 300 is shown overlaid with an example trip/service between a first location 304 and a second location 306. The example trip/service can be assigned, for example, to an autonomous vehicle 320 by a remote computing system. The autonomous vehicle 320 can be, for example, the same type of vehicle as autonomous vehicle 310. The example trip/service can include transporting passengers or cargo between the first location 304 and the second location 306. In some implementations, the example trip/service can include travel to or through one or more intermediate locations, such as to onload or offload passengers or cargo. In some implementations, the example trip/service can be prescheduled (e.g., for regular traversal, such as on a transportation schedule). In some implementations, the example trip/service can be on-demand (e.g., as requested by or for performing a taxi, rideshare, ride hailing, courier, delivery service, etc.).

With reference to FIG. 3C, in another example, an operational environment can include an open travel way environment 330. An autonomous platform can include an autonomous vehicle 350 controlled by the autonomy system 200. This can include an autonomous tractor for an autonomous truck. In some implementations, the autonomous vehicle 350 can be configured for high payload transport (e.g., transporting freight or other cargo or passengers in quantity), such as for long distance, high payload transport. For instance, the autonomous vehicle 350 can include one or more cargo platform attachments such as a trailer 352. Although depicted as a towed attachment in FIG. 3C, in some implementations one or more cargo platforms can be integrated into (e.g., attached to the chassis of, etc.) the autonomous vehicle 350 (e.g., as in a box van, step van, etc.).

With reference to FIG. 3D, a selected overhead view of open travel way environment 330 is shown, including travel ways 332, an interchange 334, transfer hubs 336 and 338, access travel ways 340, and locations 342 and 344. In some implementations, an autonomous vehicle (e.g., the autonomous vehicle 310 or the autonomous vehicle 350) can be assigned an example trip/service to traverse the one or more travel ways 332 (optionally connected by the interchange 334) to transport cargo between the transfer hub 336 and the transfer hub 338. For instance, in some implementations, the example trip/service includes a cargo delivery/transport service, such as a freight delivery/transport service. The example trip/service can be assigned by a remote computing system. In some implementations, the transfer hub 336 can be an origin point for cargo (e.g., a depot, a warehouse, a facility, etc.) and the transfer hub 338 can be a destination point for cargo (e.g., a retailer, etc.). However, in some implementations, the transfer hub 336 can be an intermediate point along a cargo item's ultimate journey between its respective origin and its respective destination. For instance, a cargo item's origin can be situated along the access travel ways 340 at the location 342. The cargo item can accordingly be transported to transfer hub 336 (e.g., by a human-driven vehicle, by the autonomous vehicle 310, etc.) for staging. At the transfer hub 336, various cargo items can be grouped or staged for longer distance transport over the travel ways 332.

In some implementations of an example trip/service, a group of staged cargo items can be loaded onto an autonomous vehicle (e.g., the autonomous vehicle 350) for transport to one or more other transfer hubs, such as the transfer hub 338. For instance, although not depicted, it is to be understood that the open travel way environment 330 can include more transfer hubs than the transfer hubs 336 and 338 and can include more travel ways 332 interconnected by more interchanges 334. A simplified map is presented here for purposes of clarity only. In some implementations, one or more cargo items transported to the transfer hub 338 can be distributed to one or more local destinations (e.g., by a human-driven vehicle, by the autonomous vehicle 310, etc.), such as along the access travel ways 340 to the location 344. In some implementations, the example trip/service can be prescheduled (e.g., for regular traversal, such as on a transportation schedule). In some implementations, the example trip/service can be on-demand (e.g., as requested by or for performing a chartered passenger transport or freight delivery service).

To improve the performance of an autonomous platform, such as an autonomous vehicle controlled at least in part using autonomy system 200 (e.g., the autonomous vehicles 310 or 350), the planning system 250 can implement validation techniques according to example aspects of the present disclosure.

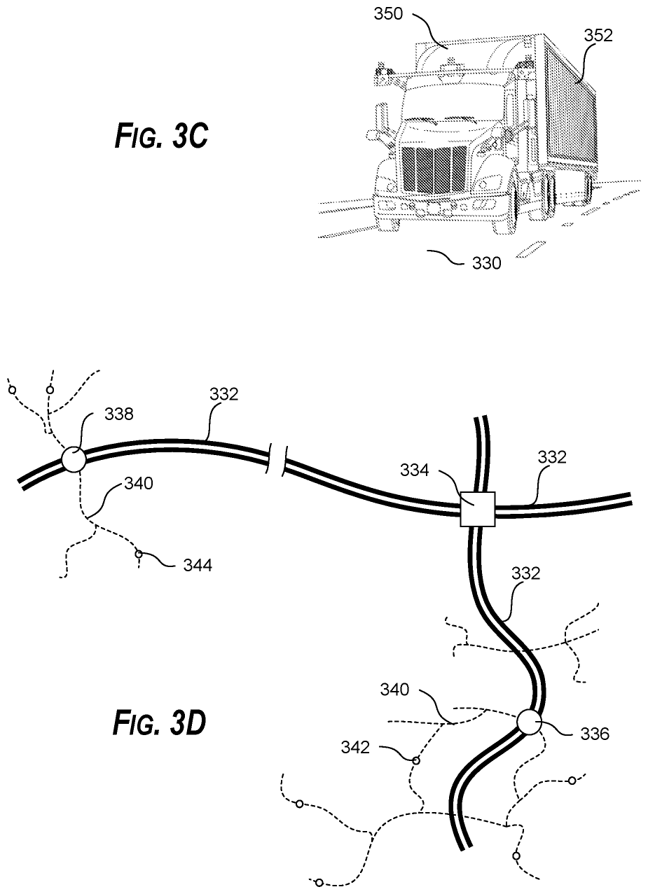

FIG. 4 is a block diagram of a validation system 400, according to some implementations of the present disclosure. Although FIG. 4 illustrates an example implementation of a validation system 400 having various components, it is to be understood that the components can be rearranged, combined, omitted, etc. within the scope of and consistent with the present disclosure.

Validation system 400 can obtain data describing a driving scenario 402. Validation system 400 can pass the data describing driving scenario 402 to a user input system 410 for obtaining user input from a user. User input can indicate a reference decision 412 that the user considers to be a correct decision for navigating driving scenario 402 for a given validity interval 414. Reference decision(s) 412 and validity interval(s) 414 can together form one or more label(s) 416 for driving scenario 402 (e.g., corresponding to one or more objects represented in driving scenario 402). Validation system 400 can pass the data describing driving scenario 402 to a system under test (SUT) 420. SUT 420 can output an SUT decision 422 for navigating driving scenario 402. A validator 430 can compare reference decision 412 and SUT decision 422 and output a validation state 440 that indicates a validity of at least a portion of SUT 420 based on SUT decision 420.

Validation system 400 can be or include one or more computing devices. Validation system 400 can include multiple different computing devices to implement various different portions of the described technique(s). Validation system 400 can include, for instance, user workstations or other endpoints for receipt of user input 410 (and rendering of interfaces for obtaining that input). Validation system 400 can include, for instance, server computing systems or other computing environments implementing SUT 420. Validation system 400 can include autonomous vehicle control system hardware or simulations or emulations thereof (e.g., computing systems configured for deployment onboard an autonomous vehicle) for implementing SUT 420. Validation system 400 can include, for instance, server computing systems or other computing environments implementing evaluator 430.

Driving scenario 402 can include a portion of log data that describes an environment in which a vehicle navigates. Log data can include recorded instances of real-world or simulated driving. The recorded data can include data collected by sensors onboard one or more vehicles (e.g., autonomous vehicles, non-autonomous vehicles, etc.). The recorded data can include data collected from other sources (e.g., roadside cameras, aerial vehicles, etc.). Log data from simulated scenarios can include probabilistic data, such as data sampled from a distribution fitted to a number of observations. Log data can be completely or partially synthetic. Log data can be generated by one or more machine-learned models based on an input. For instance, a snapshot of a traffic scene can provide an input to one or more machine-learned models to trigger generation of all or part of a driving scenario (e.g., generation of a three-dimensional scene, generation of an animation of a scene, generation of synthetic sensor data describing a scene, etc.).

Driving scenario 402 can describe a scene in which a vehicle can operate as well as other objects or actors in the scene that present possible choices for navigation. The scene can include, for example, a roadway in which another vehicle in an opposing lane of traffic appears to be attempting an unprotected left turn across the roadway. Such a scenario can present a number of possible choices regarding lane choice, velocity/acceleration choices, etc.

Driving scenario 402 can be a portion of the log data that describes a scene or event of interest. The scene or event of interest can include an environment, including objects, which may be other actors. The scene or event of interest can be selected to explore edge case eventualities and responses of an SUT in such eventualities. For example, a scenario can include a vehicle driving past a vehicle parked on the side of the street, a vehicle merging into traffic, a vehicle maintaining a trailing distance at a steady state cruise on a highway, etc. The scene or event of interest can be selected to validate normal operating scenarios. The scene or event of interest can be automatically or probabilistically determined based on a desired distribution of validation scenarios. For instance, a target distribution of validation scenarios may be desired to obtain a particular confidence level for the validated SUT in a distribution of deployment scenarios. The target distribution can be shaped using a cost or score associated with the validation scenarios (e.g., a cost or score associated with suboptimal performance in such scenarios). For instance, scenarios providing opportunities for high-cost errors (e.g., unprotected left turns across traffic) can be present in greater proportion in the distribution of validation scenarios as compared to scenarios providing only opportunities for low-cost errors (e.g., navigating empty parking lots).

Log data can describe multiple driving scenarios 402. In an example, sliding a time window over log data can capture a number of different driving scenarios 402. The time windows can overlap or not overlap. Multiple driving scenarios 402 can be obtained from log data by sliding a time window with a prescribed stride and skip. Driving scenarios 402 can be obtained from log data by processing log data with one or more machine-learned models trained to recognize scenes of interest and output, extract, or otherwise flag or indicate related portions of the log data.

User input system 410 can include a user interface configured for presenting the driving scenario 402 to a user for review. The user interface can include a graphical user interface. The user interface can present driving scenario 402 over a period of time. The driving scenario 402 can be presented from the perspective of a vehicle navigating the driving scenario. The vehicle can be an actor recorded in the log data. The vehicle can be an actor injected into driving scenario 402 (e.g., not recorded in the log data).

For example, user input system 410 can present a playback of a time history of log data that describes driving scenario 402. Playback can occur in real-time or at accelerated or slowed time scales.

User input system 410 can present playback from one or more viewpoints. For instance, playback can include a rendering of a view from a driver seat of a vehicle navigating driving scenario 402. Playback can include rendering a bird's eye or other overhead view of the vehicle navigating driving scenario 402 (e.g., to show context that might otherwise be obscured from view).

Playback can include a graphical rendering of an environment and actors within the environment. Playback can include a graphical rendering of recorded or generated sensor data, map data, or other such data (e.g., mapped objects, point clouds, captured image data, etc.).

User input system 410 can include a simulation system in which a user controls a simulated vehicle in a simulated environment presenting driving scenario 402. The user's control of the simulated vehicle can provide user input regarding the user's decisions in driving scenario 402. User input system 410 can include a sensor suite that monitors motion of a real-world vehicle traveling in real-world environments.

Reference decision(s) 412 can include an indication by a user of a preferred action to take to navigate driving scenario 402. For instance, for a driving scenario presenting a choice of whether to change lanes to accommodate a merging actor, a user can input a decision to change lanes.

Some example decision types include the following. A merge decision label can include a decision to yield (e.g., the vehicle should yield at the merging point, such as a right-on-red, for the actor to pass first) or do_not_yield (e.g., the vehicle should go in front of the actor at the merging point, such as a right-on-red). A nudge or following decision label can include a decision to follow (e.g., a “following” behavior related to an actor the vehicle is following behind, such as indicating that the vehicle should follow behind a bicycle that's partially in its lane); to nudge_left (e.g., the vehicle should nudge to the left of the actor); to nudge_right (e.g., the vehicle should nudge to the right of the actor); to yield (e.g., a more general notion where the vehicle should stop or concede right of way for an actor, such as when an actor vehicle doing a 3 point-turn ahead of the vehicle, the decision can be marked as yield-follow can be a subset of yield); or to ignore (e.g., the vehicle should just ignore the actor and not make any decision for that actor). A vulnerable actor decision label can include yield (e.g., the vehicle should wait for a pedestrian to cross over the vehicle's intended path) or do_not_yield (e.g., the vehicle should not yield to a distant pedestrian heading away from the vehicle's intended path). A traffic light decision label can include to stop (e.g., the vehicle should stop for a yellow light) or go (e.g., the vehicle should travel through the yellow light).

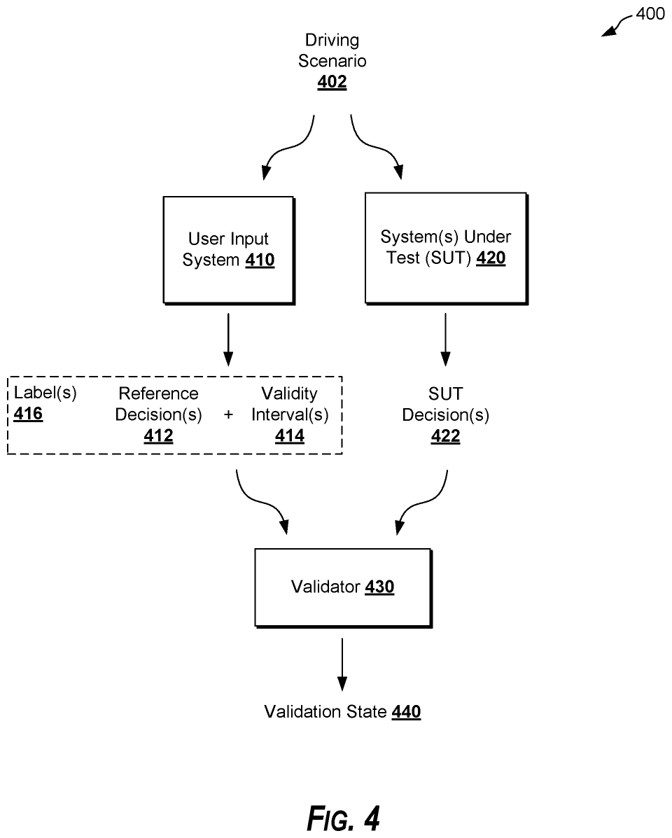

Validity interval(s) 414 for reference decision(s) 412 can indicate an interval of time for which the decision is held as the preferred course of action. FIGS. 5A and 5B illustrate a practical example.

FIG. 5A depicts an example driving scenario at a time t₁. User input system 410 can present a rendering of the driving scenario. Actor 500 is presented as traveling with heading 502. A merging actor 510 is presented as traveling with heading 512. User input system 410 can receive an input from a user indicating what action the user would take in the position of actor 500 at time 11. For instance, the user can indicate a decision to remain in the lane, remain in the lane and decelerate, change lanes, etc. The user can indicate the decision by marking a trajectory on the rendered representation of the driving scenario (e.g., for an example interface that renders the scenario in the manner shown in FIG. 5A, the user can draw a trajectory on the lanes shown).

FIG. 5B depicts an example driving scenario at a time t₂. User input system 410 can present a rendering of the driving scenario. Actor 500 is presented as traveling with heading 504. Merging actor 510 is presented as traveling with heading 514. User input system 410 can receive an input from a user indicating what action the user would take in the position of actor 500 at time t₂. For instance, the user can indicate a decision to remain in the lane, remain in the lane and decelerate, change lanes, etc.

The decision by the user at time t₁ may be different from the decision by the user at time t₂. For instance, based on the closing distance between actor 500 and actor 510, a user may be more likely to indicate a decision to change lanes to make room for merging actor 510. As such, the decision made with respect to the scenario at time t₁ can be associated with a validity interval including time t₁ but ending at some time on or before time t₂, since at time t₂ the user would take a different action.

With reference again to FIG. 4, reference decision 412 can be associated with a portion of an environment. For instance, a user can interact with user input system 410 to input a decision with respect to an object. For instance, a user can select a representation of an actor or traffic signal and input a decision made with respect to that actor or traffic signal. An example user interface can present a dropdown of available/valid decision types for the selected actor. For instance, a dropdown menu for an actor can include “yield” and “not yield” decisions available for selection.

A user can interact with user input system 410 to input a time range for the input decision. The user can manually input a time range. The user can set keyframes or time bounds of a playback sequence for a start and an end of a validity interval. The user input system 410 can automatically initiate setting of the keyframes or time bounds when a decision is input. For instance, upon receiving an input of a decision, user input system 410 can initiate an interface with which the user can interact with a timeline element to set the interval bounds. For instance, a first click on a timeline or keyframe can be associated with a lower time bound and a second click can be associated with an upper time bound. For instance, a first click can be associated with an upper time bound and a second click can be associated with a lower time bound. For instance, a particular click type (e.g., left or right) can be associated with a lower time bound and a second click type can be associated with an upper time bound. For instance, a first combination of inputs (e.g., keyboard shortcut, etc.) can be associated with a lower time bound and a second combination can be associated with an upper time bound.

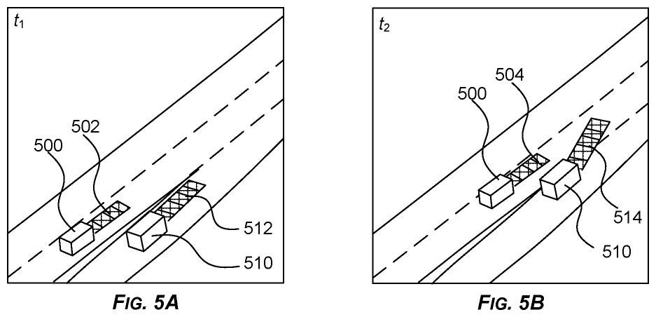

FIG. 6 depicts an illustration of an example interface 600 for interacting with user input system 410. Playback controls 602 can facilitate stepping through a timeline of a scenario in which a subject vehicle 500 is navigating. Selectable elements 604 rendered on the interface may be selectable for inputting a decision (e.g., select the stop sign to input a decision to stop at the intersection, select the yield sign to input a decision to yield at the intersection, etc.). Interface 600 can present a trajectory 606. The user can input trajectory 606 (e.g., draw) to show where the user would drive. The trajectory can be parsed to extract decisions from that trajectory. For instance, a lane selection decision can be determined from the trajectory, or other spatial decisions (e.g., with respect to other actors). The trajectory 606 can be representative of what the subject vehicle did (in the scenario) or is planning to do at the current time step.

A decisions panel 608 can provide an overview of current decision labels input for actor 500 in the scenario. The decisions panel 608 can list current decision labels under their respective decision types as well as in association with objects with respect to which the decisions are made.

A timeline can provide an interface for inputting time bounds for the labels. For instance, an interactive interface element 610 can be used to set a marker for a lower time bound. The marker can be associated with a time stamp or keyframe of the scenario playback. An interactive interface element 612 can be used to set a marker for an upper time bound. The marker can be associated with a time stamp or keyframe of the scenario playback.

Other input mechanisms can be used. Example interface 600 is provided by way of example only.

With reference again to FIG. 4, reference decision 412 can be stored as a label for driving scenario 402. Any corresponding validity interval(s) can be stored as well. Reference decision 412 and any intervals corresponding thereto can be stored in a data structure that associates reference decision 412 with driving scenario 402 and the object with respect to which reference decision 412 was made.

SUT 420 can include one or more components of an autonomous vehicle control system. SUT 420 can include one or more machine-learned models. SUT 420 can include any one or more components of autonomy system(s) 200 (e.g., localization 230, perception 240, planning 250, control 260, etc.).

SUT 420 can be implemented in a simulation or emulation environment. The simulation can be a deterministic simulation. For instance, any one or more inputs to SUT 420 can be simulated. For example, sensor data 204 can be simulated to implement any portion or the whole of autonomy system(s) 200 as SUT 420. Any intermediate state between components can likewise be simulated to operate individual components in simulation. For instance, perception outputs can be simulated (e.g., recalled from a log of perception outputs, generated, etc.) to isolate planning system 250 as SUT 420.

SUT 420 can be simulated in driving scenarios that have been labeled with reference decisions. SUT 420 can operate in simulation (or in a real-world test environment), and driving scenarios encountered in the simulation (or the real-world test environment) can be subsequently labeled.

SUT decision 422 can include an action taken—or a candidate action proposed to be taken—by SUT 420 in the simulation/test environment. For example, with reference again to FIG. 5A, heading 502 can represent a trajectory output by SUT 420 for controlling actor 500 at time 11. With reference again to FIG. 5B, heading 504 can represent a trajectory output by SUT 420 for controlling actor 500 at time t₂. These trajectories can be different from the decisions input by a user using user input system 410. For instance, a user can view the scenario depicted in FIG. 5A and enter a decision that the user would have made in that scenario, which can be the same as or different from the decision or action taken by the actor 500 controlled by SUT 420. In this manner, for instance, the user input system 410 can record a reference decision that corresponds to the scenario encountered by SUT 420.

SUT decision(s) 422 can include a set of candidate decisions. For instance, a planning system can be configured to propose a number of candidate decisions that could be made with respect to a given object.

SUT 420 can generate SUT decision(s) 422 in various different simulation context windows. For instance, an SUT 420 can output SUT decision(s) 422 at a given test time that is a cumulative result of prior SUT decisions. An SUT 420 can output SUT decision(s) 422 at a given test time that is independent of other SUT decisions.

Example techniques described herein can mitigate simulation drift. For instance, good alignment between the simulated scenario and the labeled scenario can improve label relevance. Naively simulating SUT 402 from a seed state prior to the labeled scenario can introduce drift between the state of the SUT and the state of the vehicle action that was labeled. For instance, an SUT may determine to brake prior to the labeled scenario, so that the SUT-controlled vehicle might enter the labeled scenario in a different position as compared to the vehicle action that was labeled.

A handover process can be used to mitigate such drift. For instance, a simulation can define a particular time or time period during or after which an SUT is to be validated. This time period can be referred to as “test time.” A test-time simulation (during or after which the SUT 420 output is to be validated) can occur after a preceding lead-in simulation period. The lead-in simulation period can be longer than the test-time simulation period. The lead-in simulation period can enable initializing various components of SUT 420 (e.g., state vectors, object tracks/histories, etc.). For some SUT 420, a decision at test time can be influenced by memory of past events or object tracks. Human drivers (and human users labeling scenarios) can do the same. As such, a lead-in simulation period can help align the internal states of SUT 420 with the preceding scenario for direct comparison with reference decision 412.

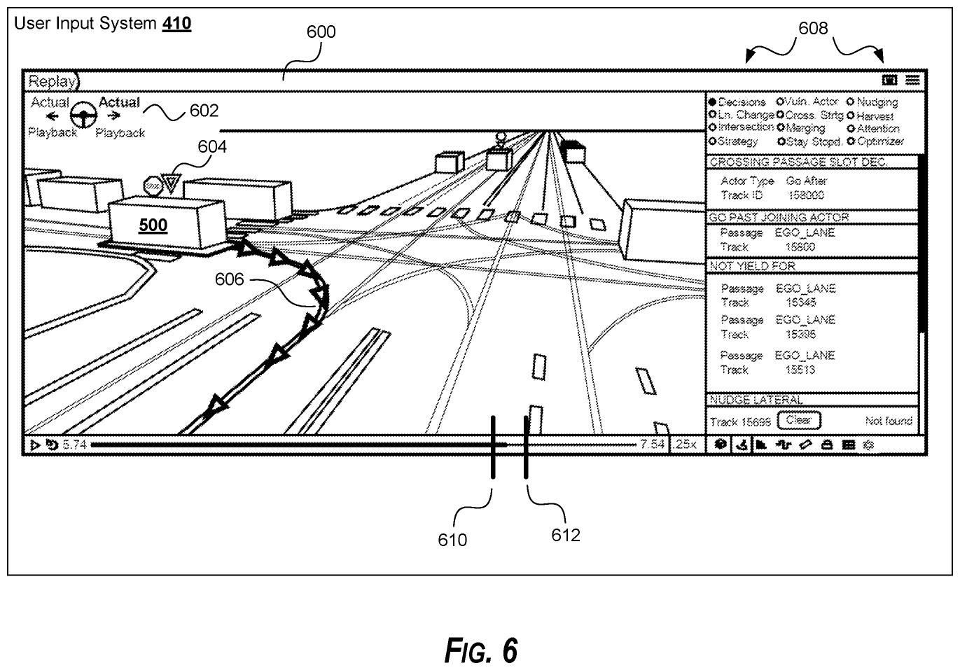

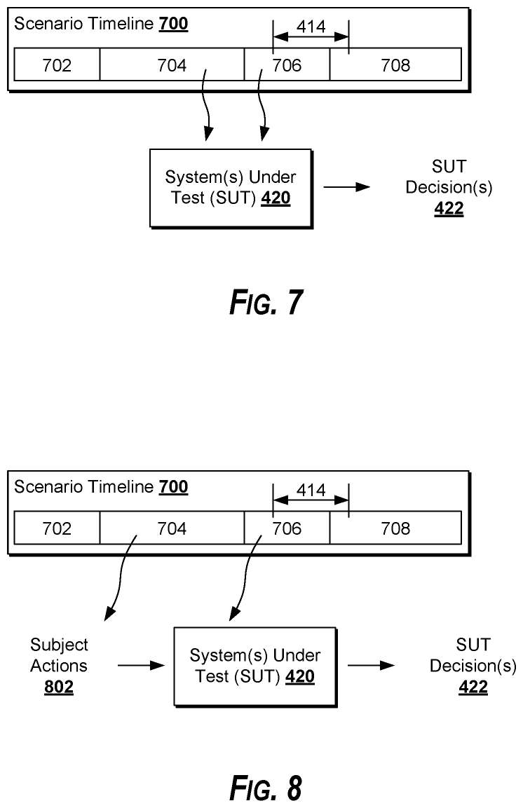

FIGS. 7 and 8 illustrate different approaches to performing the handover. FIG. 7 depicts a processing flow in which an SUT 420 can output SUT decision(s) 422 at a given test time that can be a cumulative result of prior SUT decisions. A scenario timeline 700 for a given driving scenario 402 can be considered to have a number of timeline segments 702, 704, 706, and 708. An interval associated with a “test time” can correspond to timeline segment 706. Validity interval 414 is illustrated on timeline 700. Validity interval 414 can align with the time intervals used for simulation, but validity interval 414 might not align with the time intervals used for simulation.

A lead-in simulation period can lead into the test time interval (e.g., to generate object tracks and state vectors for environmental objects to be used when making decisions in test time interval 706). For instance, an interval corresponding to timeline segment 704 can be used. For instance, SUT 420 can process data describing driving scenario 402 over an interval corresponding to timeline segment 704 to determine one or more SUT decisions during the interval corresponding to timeline segment 704. The prior SUT decisions can initialize one or more values for use at the test time. The prior SUT decisions can set a heading of the vehicle, velocity, acceleration, etc.

For driving scenarios 402 in which the data describes a subject vehicle, the prior SUT decisions can be fixed in alignment with the movements of the subject vehicle. For instance, although SUT 420 can output a number of candidate SUT decisions, for the purpose of maintaining alignment between the SUT 420 state and the subject vehicle, the SUT 420 can be forced or strongly biased to select/implement the decision that aligns with that of the subject vehicle (e.g., using injected costs/scores to bias SUT 420 toward an outcome). In this manner, prior SUT decisions and internal states in the set of candidates are available to influence decisions at test time, but the SUT 420 enters test time in alignment with the subject vehicle to ensure direct comparison between SUT decision(s) 422 and reference decision(s) 412 for the subject vehicle at test time. In this manner, for instance, SUT 420 can assume control at test time and be evaluated in context.

Interval associated with timeline segment 704 can be longer than interval associated with timeline segment 706. Interval associated with timeline segment 704 can be shorter than interval associated with timeline segment 706. Interval associated with timeline segment 704 can be, for example, about 5 minutes, and interval associated with timeline segment 706 can be, for example, about 1 minute. For instance, a ratio can be about 10:1, 5:1, 2:1, 1:1, etc., or less than or greater than any such example ratio. The intervals can be much shorter or longer. For instance, interval associated with timeline segment 706 can be about 1 second.

FIG. 8 depicts a processing flow in which an SUT 420 can output an SUT decision 422 at a given test time that can be at least partially independent of other SUT decisions. In lieu of processing the data describing driving scenario 402 over interval 704 to determine one or more SUT decisions during interval associated with timeline segment 704, subject actions 802 extracted from the data describing driving scenario 402 over interval associated with timeline segment 704 can be directly provided to SUT 420 as current or prior states of SUT 420. For instance, if SUT 420 is configured to maintain, recall, and process a history of prior actions/states, subject actions 802 can be recalled and process instead of prior actions and states organically generated by SUT 420. In this manner, for instance, the SUT decision(s) 422 at test time can be at least partially isolated from any past-time SUT behavior to provide precise evaluation of decisions made exactly at test time.

With reference again to FIG. 4, SUT decisions 422 can be candidate proposed decisions. SUT decisions 422 can include executed decisions (e.g., decisions executed in simulation). SUT decisions 422 can include an intermediate output or state of SUT 420 intercepted from a component of interest (e.g., an output sampled directly from a planner component). For instance, SUT decisions 422 can be obtained from output data representing a number of decisions (e.g., a list or tensor of decisions). SUT decisions 422 can be obtained from output data presenting a number of trajectories corresponding to various decisions.

Validator 430 can compare SUT decision(s) 422 with reference decision(s) 412. The corresponding validity intervals 414 can constrain the comparison. Validator 430 can determine a compatibility of the decisions (e.g., express agreement, lack of conflict, etc.). Validator 430 can output a positive validation state based on the comparison.

For sets of multiple SUT decisions 422, a validation state can reflect the area of least agreement/most conflict. For instance, an SUT 420 can output a set of candidate decisions. The set of candidate decisions may include ten possible choices to make with respect to a given object. Nine of the choices may agree or otherwise be compatible with a reference decision 412 (e.g., a reference decision to yield can be achieved in various ways, by braking, coasting, etc.). However, one candidate decision being incompatible (e.g., a reference decision to yield with a candidate choice to not yield) can trigger a suboptimal validation state.

Validation state(s) 440 can correspond to varying levels of strictness. In a strict configuration, for instance, any disagreement can lead to an “INVALID” state. In a relaxed configuration, a quality of the disagreement can trigger a suboptimal validation state characterized by a measure of how suboptimal the validation state is. For instance, a disagreement regarding whether to stop for a stop sign can be highly suboptimal while a disagreement regarding lane choice in a low-traffic, multi-lane scenario can be less suboptimal.

Validator 430 can generate intermediate validation state(s) during a simulation interval for computing an overall validation state. For instance, an SUT 420 can output many decisions over a simulation interval. For instance, a planning system can cycle rapidly (e.g., 10 millisecond cycle time). At each cycle the planner can determine candidate decisions and output a selected decision, etc. The simulation window can include multiple cycles, so the total set of SUT decision(s) 422 can include the decisions determined for each such cycle. A validation state can be determined based on all the decisions. A consistency metric can be determined by applying one or more statistical measures to the set of decisions or the set of intermediate validation states. A consistency metric can include a majority vote, a plurality vote, a proportion above a threshold, etc. A consistency metric can be a learned metric (e.g., a value output by a learned model trained to score a set of inputs for a desired level of consistency).

An intermediate validation state can be determined for each cycle. The validation state 440 can be determined based on the intermediate validation states. For instance, in a strict configuration, validation state 440 can be negative if any of the intermediate validation states are negative. In a relaxed configuration, validation state 440 can be negative or suboptimal based on a proportion or amount of negative or suboptimal intermediate validation states. In a relaxed configuration, validation state 440 can be negative or suboptimal based on a proportion or amount of negative or suboptimal intermediate validation states in conjunction with a measure of how negative or suboptimal the intermediate validations states are.

A smoothing operation can be applied over the intermediate validation states. For instance, a smoothing window can be applied over a buffer of intermediate validation states.

The validation state 440 can be determined based on the decisions from each cycle (e.g., without first computing intermediate validation states). For instance, in a strict configuration, validation state 440 can be negative if any of the decisions (or sets of decisions at each cycle) conflict with the reference decision. In a relaxed configuration, validation state 440 can be negative or suboptimal based on a proportion or amount of suboptimal decision sets. In a relaxed configuration, validation state 440 can be negative or suboptimal based on a proportion or amount of negative or suboptimal decision sets in conjunction with a measure of how negative or suboptimal the suboptimal decision sets are.

A smoothing operation can be applied over the decision sets. For instance, a smoothing window can be applied over a buffer of decision sets.

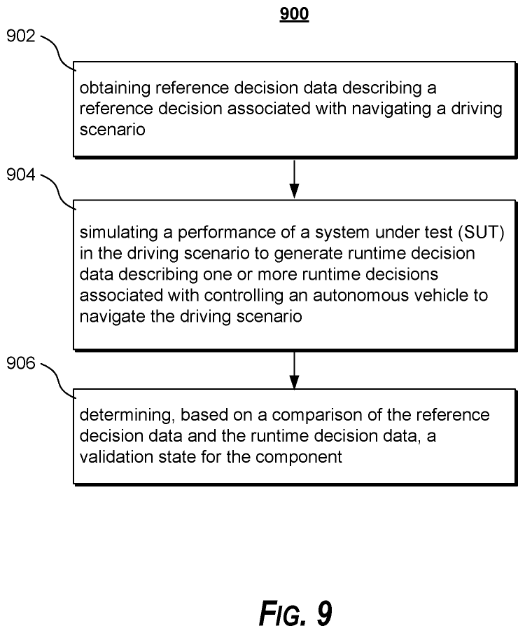

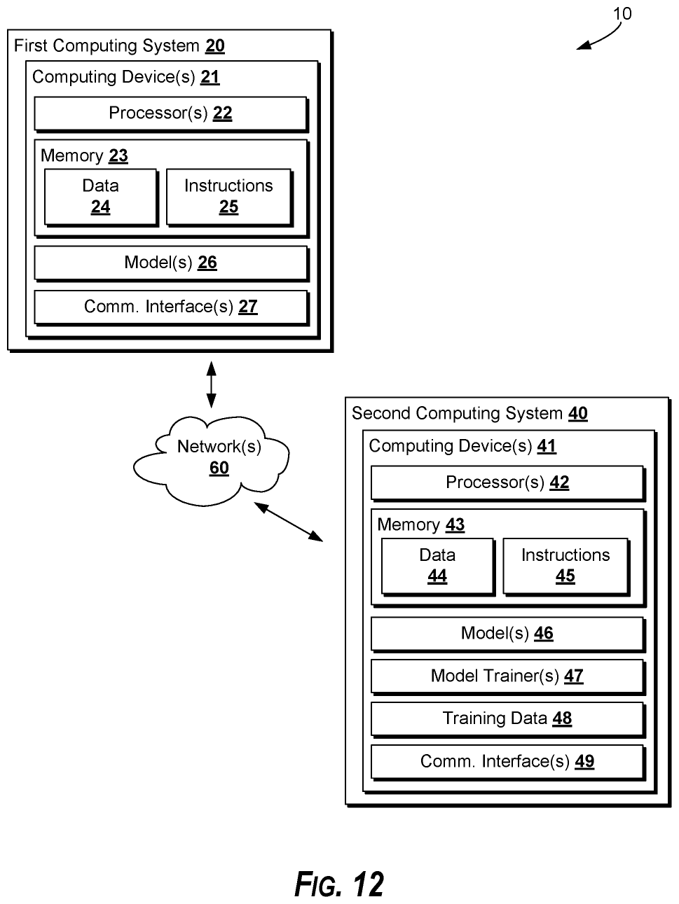

FIG. 9 is a flowchart of method 900 for performing system validation according to aspects of the present disclosure. One or more portion(s) of the method 900 can be implemented by a computing system that includes one or more computing devices such as, for example, the computing systems described with reference to the other figures (e.g., autonomous platform 110, vehicle computing system 180, remote system(s) 160, a system of FIG. 12, etc.). Each respective portion of the method 900 can be performed by any (or any combination) of one or more computing devices. Moreover, one or more portion(s) of method 900 can be implemented on the hardware components of the device(s) described herein (e.g., as in FIGS. 1, 2, 12, etc.). FIG. 9 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, or modified in various ways without deviating from the scope of the present disclosure. FIG. 9 is described with reference to elements/terms described with respect to other systems and figures for exemplary illustrated purposes and is not meant to be limiting. One or more portions of method 900 can be performed additionally, or alternatively, by other systems.

At 902, example method 900 can include obtaining reference decision data describing a reference decision associated with navigating a driving scenario. An example reference decision is reference decision 412. An example driving scenario is driving scenario 402. In some implementations of example method 900, the reference decision data can include a target action and a corresponding object identifier associated with the target action. In some implementations of example method 900, the reference decision data can include a validity interval associated with the target action.

At 904, example method 900 can include simulating a performance of a system under test (SUT) in the driving scenario to generate SUT decision data describing one or more SUT decisions associated with controlling an autonomous vehicle to navigate the driving scenario. An example SUT is SUT 420. An example one or more SUT decisions are SUT decision(s) 422. SUT decision data describing one or more SUT decisions can include a data array, list, tensor, or other data structure representing the one or more SUT decisions.

In some implementations of example method 900, simulating a performance of an SUT (e.g., SUT 420) can include executing one or more components of an autonomous vehicle control system (e.g., autonomous system(s) 200) in a simulation environment.

In some implementations of example method 900, the driving scenario is obtained from real-world log data. In some implementations of example method 900, example method 900 can include generating the SUT decision data by processing, using the SUT, the real-world log data.

In some implementations of example method 900, the driving scenario is obtained from simulation log data. Simulation log data can include log data generated by simulating operation of the SUT. Simulation log data can include log data generated by synthesizing an environment in which to cause the SUT to operate. For instance, simulation log data can include data obtained by simulating an environment (e.g., generating sensor data, map data, or other data descriptive of the environment). In some implementations of example method 900, example method 900 can include generating the SUT decision data by processing, using the SUT, the simulation log data. In some implementations of example method 900, the driving scenario is generated in simulation for testing the SUT. In some implementations of example method 900, simulating the performance of the SUT comprises generating simulation log data describing the driving scenario.

In some implementations of example method 900, example method 900 includes obtaining log data recording internal operating states of the SUT. For instance, an internal operating state can include a proposed candidate decision for navigating a simulated environment. The proposed candidate decision might not be selected by the SUT for execution, but the proposed candidate decision can be logged and used to validate the SUT.

At 906, example method 900 can include determining, based on a comparison of the reference decision data and the SUT decision data, a validation state for the SUT.

In some implementations of example method 900, an interface can facilitate obtaining the reference decision. In some implementations of example method 900, example method 900 at 902 can include outputting, to a display device for display to a user and based on the real-world log data (or simulation log data), a graphical representation of the driving scenario. In some implementations of example method 900, example method 900 at 902 can include receiving, from an input device, input data descriptive of the reference decision. In some implementations of example method 900, the reference decision can indicate how the user would choose to navigate the driving scenario.

In some implementations of example method 900, example method 900 can include simulating the performance of the SUT while managing simulation drift.

In some implementations of example method 900, log data (e.g., real-world log data or simulation log data) can include data describing the driving scenario at a test time and data describing the driving scenario at one or more preceding times. In some implementations of example method 900, example method 900 at 904 can include generating the SUT decision data by processing, using the SUT, the data describing the driving scenario at the test time in view of the data describing the driving scenario at the one or more preceding times.

In some implementations of example method 900, example method 900 can include simulating the performance of the SUT over a time interval preceding a test-time simulation interval.

In some implementations of example method 900, log data (e.g., real-world log data or simulation log data) can include data describing actions of a subject vehicle. In some implementations of example method 900, example method 900 at 904 can include causing the SUT to implement the actions of the subject vehicle at the one or more preceding times and causing the SUT to generate the SUT decision data at the test time.

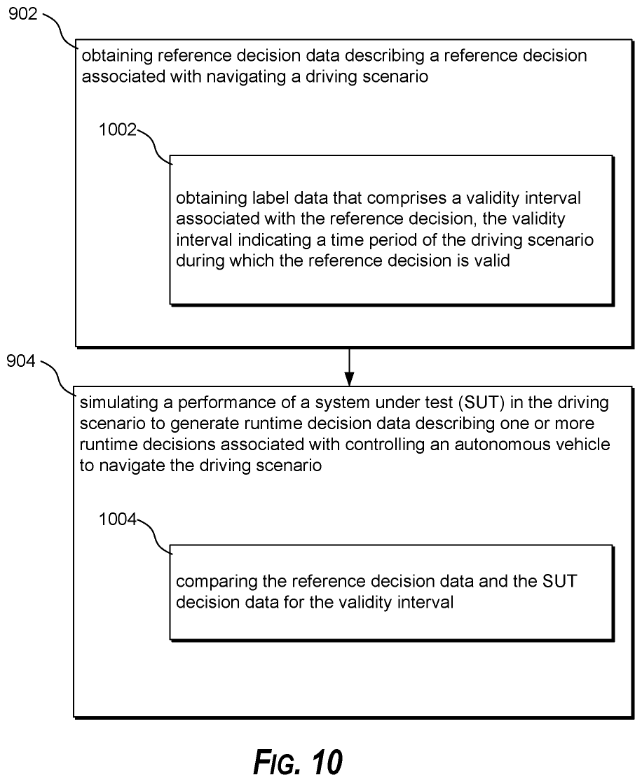

FIG. 10 is a flowchart of an example implementation of example method 900. In some implementations of example method 900, example method 900 at 902 can further include, at 1002, obtaining label data that includes a validity interval associated with the reference decision. The validity interval can indicate a time period of the driving scenario during which the reference decision is valid.

In some implementations of example method 900, example method 900 at 904 can further include, at 1004, comparing the reference decision data and the SUT decision data for the validity interval. In some implementations of example method 900, example method 900 can include simulating the performance of the SUT over a preliminary simulation period prior to the validity interval.

In some implementations of example method 900, example method 900 can include validating the SUT based on a plurality of SUT decisions. For instance, an SUT can be a component of an autonomous vehicle controls system that can cycle multiple times within a simulation interval. In some implementations of example method 900, example method 900 at 906 can include outputting a negative validation state based on determining that at least one of the one or more SUT decisions conflicts with the reference decision.

In some implementations of example method 900, the SUT can include a motion planner of an autonomous vehicle control system of the autonomous vehicle. In some implementations of example method 900, example method 900 at 904 can include obtaining data descriptive of one or more strategies determined by the motion planner, wherein a respective strategy of the one or more strategies includes one or more respective SUT decisions. In some implementations of example method 900, example method 900 at 906 can include determining a consistency metric based on a comparison of the one or more respective SUT decisions and the reference decision.

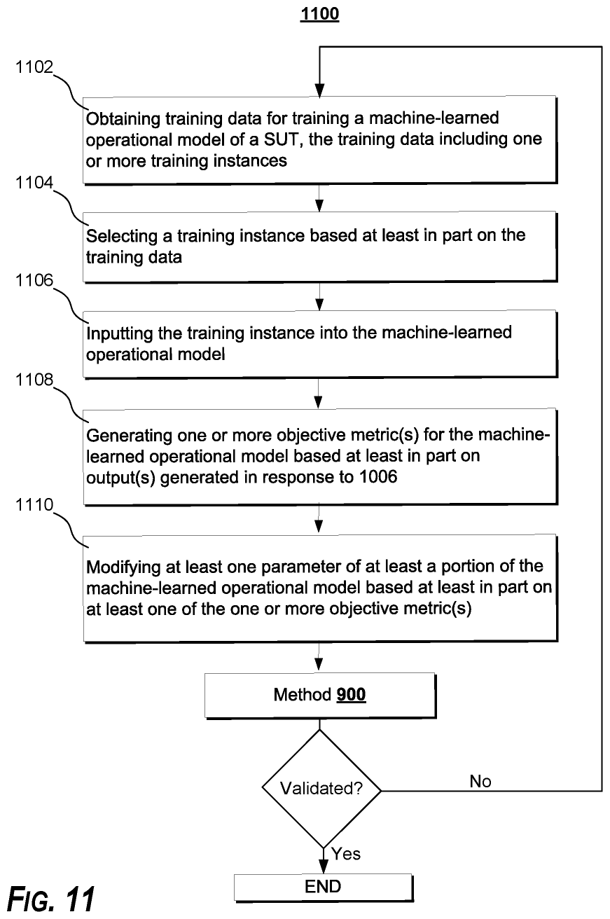

In some implementations of example method 900, example method 900 includes re-training, based on the validation state, a machine-learned model associated with the SUT. For instance, FIG. 11 depicts a flowchart of method 1100 for training one or more machine-learned operational models according to aspects of the present disclosure. For instance, an operational system (e.g., an SUT 420) can include a machine-learned operational model.

One or more portion(s) of the method 1100 can be implemented by a computing system that includes one or more computing devices such as, for example, the computing systems described with reference to the other figures (e.g., autonomous platform 110, vehicle computing system 180, remote system(s) 160, a system of FIG. 12, etc.). Each respective portion of the method 1100 can be performed by any (or any combination) of one or more computing devices. Moreover, one or more portion(s) of method 1100 can be implemented on the hardware components of the device(s) described herein (e.g., as in FIGS. 1, 2, 12, etc.), for example, to validate one or more systems or models. FIG. 11 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, or modified in various ways without deviating from the scope of the present disclosure. FIG. 11 is described with reference to elements/terms described with respect to other systems and figures for exemplary illustrated purposes and is not meant to be limiting. One or more portions of method 1100 can be performed additionally, or alternatively, by other systems.

At 1102, method 1100 can include obtaining training data for training a machine-learned operational model. The training data can include a plurality of training instances (e.g., reference planning data, such as labeled trajectories or strategies based on expert demonstrations).

The training data can be collected using one or more autonomous platforms (e.g., autonomous platform 110) or the sensors thereof as the autonomous platform is within its environment. By way of example, the training data can be collected using one or more autonomous vehicle(s) (e.g., autonomous platform 110, autonomous vehicle 310, autonomous vehicle 350, etc.) or sensors thereof as the vehicle(s) operates along one or more travel ways. In some examples, the training data can be collected using other sensors, such as mobile-device-based sensors, ground-based sensors, aerial-based sensors, satellite-based sensors, or substantially any sensor interface configured for obtaining and/or recording measured data.

The training data can include a plurality of training sequences divided between multiple datasets (e.g., a training dataset, a validation dataset, or testing dataset). Each training sequence can include a plurality of pre-recorded perception datapoints, point clouds, images, etc. In some implementations, each sequence can include LIDAR point clouds (e.g., collected using LIDAR sensors of an autonomous platform), images (e.g., collected using mono or stereo imaging sensors, etc.), and the like. For instance, in some implementations, a plurality of images can be scaled for training and evaluation.

At 1104, method 1100 can include selecting a training instance based at least in part on the training data.

At 1106, method 1100 can include inputting the training instance into the machine-learned operational model.

At 1108, the method 1100 can include generating one or more loss metric(s) and/or one or more objective(s) for the machine-learned operational model based on output(s) of at least a portion of the machine-learned operational model and label(s) associated with the training instances.

At 1110, method 1100 can include modifying at least one parameter of at least a portion of the machine-learned operational model based at least in part on at least one of the loss metric(s) and/or at least one of the objective(s). For example, a computing system can modify at least a portion of the machine-learned operational model based at least in part on at least one of the loss metric(s) and/or at least one of the objective(s).

In some implementations, the machine-learned operational model can be trained in an end-to-end manner. For example, in some implementations, the machine-learned operational model can be fully differentiable.

After being updated, the operational model or the operational system including the operational model can be provided for validation (e.g., according to example implementations of method 1100, etc.). In some implementations, the validation system 400 can evaluate or validate the operational system. The validation system 400 can trigger retraining, decommissioning, etc. of the operational system based on, for example, failure to satisfy a validation threshold in one or more areas.

FIG. 12 is a block diagram of an example computing ecosystem 10 according to example implementations of the present disclosure. The example computing ecosystem 10 can include a first computing system 20 and a second computing system 40 that are communicatively coupled over one or more networks 60. In some implementations, the first computing system 20 or the second computing 40 can implement one or more of the systems, operations, or functionalities described herein for validating one or more systems or operational systems (e.g., the remote system(s) 160, the onboard computing system(s) 180, the autonomy system(s) 200, etc.).

In some implementations, the first computing system 20 can be included in an autonomous platform and be utilized to perform the functions of an autonomous platform as described herein. For example, the first computing system 20 can be located onboard an autonomous vehicle and implement autonomy system(s) for autonomously operating the autonomous vehicle. In some implementations, the first computing system 20 can represent the entire onboard computing system or a portion thereof (e.g., the localization system 230, the perception system 240, the planning system 250, the control system 260, or a combination thereof, etc.). In other implementations, the first computing system 20 may not be located onboard an autonomous platform. The first computing system 20 can include one or more distinct physical computing devices 21.

The first computing system 20 (e.g., the computing device(s) 21 thereof) can include one or more processors 22 and a memory 23. The one or more processors 22 can be any suitable processing device (e.g., a processor core, a microprocessor, an ASIC, a FPGA, a controller, a microcontroller, etc.) and can be one processor or a plurality of processors that are operatively connected. Memory 23 can include one or more non-transitory computer-readable storage media, such as RAM, ROM, EEPROM, EPROM, one or more memory devices, flash memory devices, etc., and combinations thereof.

Memory 23 can store information that can be accessed by the one or more processors 22. For instance, the memory 23 (e.g., one or more non-transitory computer-readable storage media, memory devices, etc.) can store data 24 that can be obtained (e.g., received, accessed, written, manipulated, created, generated, stored, pulled, downloaded, etc.). The data 24 can include, for instance, sensor data, map data, data associated with autonomy functions (e.g., data associated with the perception, planning, or control functions), simulation data, or any data or information described herein. In some implementations, the first computing system 20 can obtain data from one or more memory device(s) that are remote from the first computing system 20.

Memory 23 can store computer-readable instructions 25 that can be executed by the one or more processors 22. Instructions 25 can be software written in any suitable programming language or can be implemented in hardware. Additionally, or alternatively, instructions 25 can be executed in logically or virtually separate threads on the processor(s) 22.

For example, the memory 23 can store instructions 25 that are executable by one or more processors (e.g., by the one or more processors 22, by one or more other processors, etc.) to perform (e.g., with the computing device(s) 21, the first computing system 20, or other system(s) having processors executing the instructions) any of the operations, functions, or methods/processes (or portions thereof) described herein. For example, operations can include implementing system validation (e.g., as described herein).

In some implementations, the first computing system 20 can store or include one or more models 26. In some implementations, the models 26 can be or can otherwise include one or more machine-learned models (e.g., a machine-learned operational system, etc.). As examples, the models 26 can be or can otherwise include various machine-learned models such as, for example, regression networks, generative adversarial networks, neural networks (e.g., deep neural networks), support vector machines, decision trees, ensemble models, k-nearest neighbors models, Bayesian networks, or other types of models including linear models or non-linear models. Example neural networks include feed-forward neural networks, recurrent neural networks (e.g., long short-term memory recurrent neural networks), convolutional neural networks, or other forms of neural networks. For example, the first computing system 20 can include one or more models for implementing subsystems of the autonomy system(s) 200, including any of: the localization system 230, the perception system 240, the planning system 250, or the control system 260.

In some implementations, the first computing system 20 can obtain the one or more models 26 using communication interface(s) 27 to communicate with the second computing system 40 over the network(s) 60. For instance, the first computing system 20 can store the model(s) 26 (e.g., one or more machine-learned models) in memory 23. The first computing system 20 can then use or otherwise implement the models 26 (e.g., by the processors 22). By way of example, the first computing system 20 can implement the model(s) 26 to localize an autonomous platform in an environment, perceive an autonomous platform's environment or objects therein, plan one or more future states of an autonomous platform for moving through an environment, control an autonomous platform for interacting with an environment, etc.

The second computing system 40 can include one or more computing devices 41. The second computing system 40 can include one or more processors 42 and a memory 43. The one or more processors 42 can be any suitable processing device (e.g., a processor core, a microprocessor, an ASIC, a FPGA, a controller, a microcontroller, etc.) and can be one processor or a plurality of processors that are operatively connected. The memory 43 can include one or more non-transitory computer-readable storage media, such as RAM, ROM, EEPROM, EPROM, one or more memory devices, flash memory devices, etc., and combinations thereof.

Memory 43 can store information that can be accessed by the one or more processors 42. For instance, the memory 43 (e.g., one or more non-transitory computer-readable storage media, memory devices, etc.) can store data 44 that can be obtained. The data 44 can include, for instance, sensor data, model parameters, map data, simulation data, simulated environmental scenes, simulated sensor data, data associated with vehicle trips/services, or any data or information described herein. In some implementations, the second computing system 40 can obtain data from one or more memory device(s) that are remote from the second computing system 40.

Memory 43 can also store computer-readable instructions 45 that can be executed by the one or more processors 42. The instructions 45 can be software written in any suitable programming language or can be implemented in hardware. Additionally, or alternatively, the instructions 45 can be executed in logically or virtually separate threads on the processor(s) 42.

For example, memory 43 can store instructions 45 that are executable (e.g., by the one or more processors 42, by the one or more processors 22, by one or more other processors, etc.) to perform (e.g., with the computing device(s) 41, the second computing system 40, or other system(s) having processors for executing the instructions, such as computing device(s) 21 or the first computing system 20) any of the operations, functions, or methods/processes described herein. This can include, for example, the functionality of the autonomy system(s) 200 (e.g., localization, perception, planning, control, etc.) or other functionality associated with an autonomous platform (e.g., remote assistance, mapping, fleet management, trip/service assignment and matching, etc.). This can also include, for example, validating a machined-learned operational system.

In some implementations, second computing system 40 can include one or more server computing devices. In the event that the second computing system 40 includes multiple server computing devices, such server computing devices can operate according to various computing architectures, including, for example, sequential computing architectures, parallel computing architectures, or some combination thereof.

Additionally, or alternatively to, the model(s) 26 at the first computing system 20, the second computing system 40 can include one or more models 46. As examples, the model(s) 46 can be or can otherwise include various machine-learned models (e.g., a machine-learned operational system, etc.) such as, for example, regression networks, generative adversarial networks, neural networks (e.g., deep neural networks), support vector machines, decision trees, ensemble models, k-nearest neighbors models, Bayesian networks, or other types of models including linear models or non-linear models. Example neural networks include feed-forward neural networks, recurrent neural networks (e.g., long short-term memory recurrent neural networks), convolutional neural networks, or other forms of neural networks. For example, the second computing system 40 can include one or more models of the autonomy system(s) 200.

In some implementations, the second computing system 40 or the first computing system 20 can train one or more machine-learned models of the model(s) 26 or the model(s) 46 through the use of one or more model trainers 47 and training data 48. The model trainer(s) 47 can train any one of the model(s) 26 or the model(s) 46 using one or more training or learning algorithms. One example training technique is backwards propagation of errors. In some implementations, the model trainer(s) 47 can perform supervised training techniques using labeled training data. In other implementations, the model trainer(s) 47 can perform unsupervised training techniques using unlabeled training data. In some implementations, the training data 48 can include simulated training data (e.g., training data obtained from simulated scenarios, inputs, configurations, environments, etc.). In some implementations, the second computing system 40 can implement simulations for obtaining the training data 48 or for implementing the model trainer(s) 47 for training or testing the model(s) 26 or the model(s) 46. By way of example, the model trainer(s) 47 can train one or more components of a machine-learned model for the autonomy system(s) 200 through unsupervised training techniques using an objective function (e.g., costs, rewards, heuristics, constraints, etc.). In some implementations, the model trainer(s) 47 can perform a number of generalization techniques to improve the generalization capability of the model(s) being trained. Generalization techniques include weight decays, dropouts, or other techniques.

For example, in some implementations, the second computing system 40 can generate training data 48 according to example aspects of the present disclosure. For instance, the second computing system 40 can generate training data 48. For instance, the second computing system 40 can implement methods according to example aspects of the present disclosure. The second computing system 40 can use the training data 48 to train model(s) 26. For example, in some implementations, the first computing system 20 can include a computing system onboard or otherwise associated with a real or simulated autonomous vehicle. In some implementations, model(s) 26 can include perception or machine vision model(s) configured for deployment onboard or in service of a real or simulated autonomous vehicle. In this manner, for instance, the second computing system 40 can provide a training pipeline for training model(s) 26.

The first computing system 20 and the second computing system 40 can each include communication interfaces 27 and 49, respectively. The communication interfaces 27, 49 can be used to communicate with each other or one or more other systems or devices, including systems or devices that are remotely located from the first computing system 20 or the second computing system 40. The communication interfaces 27, 49 can include any circuits, components, software, etc. for communicating with one or more networks (e.g., the network(s) 60). In some implementations, the communication interfaces 27, 49 can include, for example, one or more of a communications controller, receiver, transceiver, transmitter, port, conductors, software or hardware for communicating data.

The network(s) 60 can be any type of network or combination of networks that allows for communication between devices. In some implementations, the network(s) can include one or more of a local area network, wide area network, the Internet, secure network, cellular network, mesh network, peer-to-peer communication link or some combination thereof and can include any number of wired or wireless links. Communication over the network(s) 60 can be accomplished, for instance, through a network interface using any type of protocol, protection scheme, encoding, format, packaging, etc.

FIG. 12 illustrates one example computing ecosystem 10 that can be used to implement the present disclosure. Other systems can be used as well. For example, in some implementations, the first computing system 20 can include the model trainer(s) 47 and the training data 48. In such implementations, the model(s) 26, 46 can be both trained and used locally at the first computing system 20. As another example, in some implementations, the computing system 20 may not be connected to other computing systems. Additionally, components illustrated or discussed as being included in one of the computing systems 20 or 40 can instead be included in another one of the computing systems 20 or 40.

Computing tasks discussed herein as being performed at computing device(s) remote from the autonomous platform (e.g., autonomous vehicle) can instead be performed at the autonomous platform (e.g., via a vehicle computing system of the autonomous vehicle), or vice versa. Such configurations can be implemented without deviating from the scope of the present disclosure. The use of computer-based systems allows for a great variety of possible configurations, combinations, and divisions of tasks and functionality between and among components. Computer-implemented operations can be performed on a single component or across multiple components. Computer-implemented tasks or operations can be performed sequentially or in parallel. Data and instructions can be stored in a single memory device or across multiple memory devices.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.”

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

What is claimed is:

1. A computer-implemented method, comprising:
(a) obtaining reference decision data describing:
a reference decision associated with navigating a driving scenario, wherein the reference decision data comprises a target action and a corresponding object identifier associated with the target action; and
label data that comprises a validity interval associated with the reference decision, the validity interval indicating a time period of the driving scenario during which the reference decision is valid;
(b) simulating a performance of a system under test (SUT) in the driving scenario to generate SUT decision data describing one or more SUT decisions associated with controlling an autonomous vehicle to navigate the driving scenario; and
(c) determining, based on a comparison of the reference decision data and the SUT decision data, a validation state for the SUT.

2. The computer-implemented method of claim 1, wherein the driving scenario is obtained from real-world log data.

3. The computer-implemented method of claim 2, wherein (a) comprises:
outputting, to a display device for display to a user and based on the real-world log data, a graphical representation of the driving scenario; and
receiving, from an input device, input data descriptive of the reference decision,
wherein the reference decision indicates how the user would choose to navigate the driving scenario.

4. The computer-implemented method of claim 2, wherein (b) comprises:
generating the SUT decision data by processing, using the SUT, the real-world log data.

5. The computer-implemented method of claim 4,
wherein the real-world log data comprises data describing the driving scenario at a test time and data describing the driving scenario at one or more preceding times; and
wherein (b) comprises generating the SUT decision data by processing, using the SUT, the data describing the driving scenario at the test time in view of the data describing the driving scenario at the one or more preceding times.

6. The computer-implemented method of claim 5,
wherein the real-world log data comprises data describing actions of a subject vehicle; and
wherein (b) comprises causing the SUT to implement the actions of the subject vehicle at the one or more preceding times and causing the SUT to generate the SUT decision data at the test time.

7. The computer-implemented method of claim 1, wherein the driving scenario is generated in simulation for testing the SUT, and wherein simulating the performance of the SUT comprises generating simulation log data describing the driving scenario.

8. The computer-implemented method of claim 7, wherein (a) comprises:
outputting, to a display device for display to a user and based on the simulation log data, a graphical representation of the driving scenario; and
receiving, from an input device, input data descriptive of the reference decision,
wherein the reference decision indicates how the user would choose to navigate the driving scenario.

9. The computer-implemented method of claim 1, wherein (b) comprises:
obtaining log data recording internal operating states of the SUT.

10. The computer-implemented method of claim 1, wherein (c) comprises:
comparing the reference decision data and the SUT decision data for the validity interval.

11. The computer-implemented method of claim 10, wherein (b) comprises simulating the performance of the SUT over a preliminary simulation period prior to the validity interval.

12. The computer-implemented method of claim 1, wherein (c) comprises:
outputting a negative validation state based on determining that at least one of the one or more SUT decisions conflicts with the reference decision.

13. The computer-implemented method of claim 1, wherein the SUT comprises a motion planner of an autonomous vehicle control system of the autonomous vehicle, and wherein (c) comprises:
obtaining data descriptive of one or more strategies determined by the motion planner, wherein a respective strategy of the one or more strategies comprises one or more respective SUT decisions; and
determining a consistency metric based on a comparison of the one or more respective SUT decisions and the reference decision.

14. The computer-implemented method of claim 1, comprising:
re-training, based on the validation state, a machine-learned model associated with the SUT.

15. A computing system comprising:
one or more processors; and
one or more non-transitory computer-readable media storing instructions that are executable by the one or more processors to cause the computing system to perform operations, the operations comprising:
(a) obtaining reference decision data describing:
a reference decision associated with navigating a driving scenario, wherein the reference decision data comprises a target action and a corresponding object identifier associated with the target action; and
label data that comprises a validity interval associated with the reference decision, the validity interval indicating a time period of the driving scenario during which the reference decision is valid;
(b) simulating a performance of a system under test (SUT) in the driving scenario to generate SUT decision data describing one or more SUT decisions associated with controlling an autonomous vehicle to navigate the driving scenario; and
(c) determining, based on a comparison of the reference decision data and the SUT decision data, a validation state for the SUT.

16. The computing system of claim 15, wherein (c) comprises:
comparing the reference decision data and the SUT decision data for the validity interval.

17. The computing system of claim 16, wherein (b) comprises simulating the performance of the SUT over a preliminary simulation period prior to the validity interval.

18. The computing system of claim 15, wherein:
the driving scenario is obtained from real-world log data; and
(b) comprises generating the SUT decision data by processing, using the SUT, the real-world log data.

19. The computing system of claim 18, wherein:
the real-world log data comprises data describing the driving scenario at a test time and data describing the driving scenario at one or more preceding times; and
(b) comprises generating the SUT decision data by processing, using the SUT, the data describing the driving scenario at the test time in view of the data describing the driving scenario at the one or more preceding times.

20. One or more non-transitory computer-readable media storing instructions that are executable by one or more processors to cause a computing system to perform operations, the operations comprising:
(a) obtaining reference decision data describing:
a reference decision associated with navigating a driving scenario, wherein the reference decision data comprises a target action and a corresponding object identifier associated with the target action; and
label data that comprises a validity interval associated with the reference decision, the validity interval indicating a time period of the driving scenario during which the reference decision is valid;
(b) simulating a performance of a system under test (SUT) in the driving scenario to generate SUT decision data describing one or more SUT decisions associated with controlling an autonomous vehicle to navigate the driving scenario; and
(c) determining, based on a comparison of the reference decision data and the SUT decision data, a validation state for the SUT.
